(19) United States
(12) Patent Application Publication
(10) Pub. No.: US 2025/0139344 A1
(43) Pub. Date: May 1, 2025

(54) INTEGRATED CHARGE PUMP TESTING CIRCUITS

(71) Applicant: Western Digital Technologies, Inc., San Jose, CA (US)

(72) Inventors: Keyur Payak, Milpitas, CA (US); Zhenqian Jian, Shanghai (CN); Khin Htoo, Sunnyvale, CA (US); Tushar Negi, Milpitas, CA (US); Primit Modi, San Jose, CA (US)

(73) Assignee: Western Digital Technologies, Inc., San Jose, CA (US)

(21) Appl. No.: 18/494,852

(22) Filed: Oct. 26, 2023

(51) Int. Cl. G06F 30/333

(52) U.S. Cl. CPC G06F 30/333

(57) ABSTRACT

An apparatus includes one or more control circuits configured to connect to a plurality of nonvolatile memory cells. The control circuits are configured to count a number of pulses sent to switches of a charge pump, record a count of the number of pulses sent to the switches and send the count of the number of pulses in response to a request for the count of the recorded number of pulses.

### BACKGROUND

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power (e.g., a battery).

One type of non-volatile memory has strings of non-volatile memory cells that have a select transistor at each end of the string. Typically, such strings are referred to as NAND strings. A NAND string may have a drain side select transistor at one end that connects the string to a bit line. A NAND string may have a source side select transistor at one end that connects the string to a source line. The non-volatile memory cells may also be referred to as non-volatile memory cell transistors, with the channels of the non-volatile memory cell transistors collectively being referred to as a NAND string channel.

Operating a nonvolatile memory may include applying various voltages to memory cells in order to program, read and erase memory cells. In some cases, suitable voltages may be generated from a supply voltage using one or more charge pumps. A charge pump may be required to meet certain metrics (e.g., output voltage and current) to ensure that a nonvolatile memory operates satisfactorily. Charge pump testing may determine if charge pumps meet appropriate metrics.

### BRIEF DESCRIPTION OF THE DRAWINGS

Like-numbered elements refer to common components in the different figures.

FIG. 1 (FIG. 1) is a functional block diagram of a memory device.

FIGS. 2A-B are block diagrams depicting embodiments of a memory system.

FIG. 3 is a perspective view of a portion of one embodiment of a monolithic three dimensional memory structure.

FIG. 4 illustrates aspects of programming operations according to an example.

FIG. 5 illustrates aspects of erasing operations according to an example.

FIG. 6A depicts an example implementation of a charge pump configured as a single-stage charge pump.

FIG. 6B depicts an example implementation of a charge pump configured as a voltage multiplier.

FIG. 6C depicts an example implementation of a charge pump configured as a single-stage, multi-capacitor charge pump.

FIG. 6D depicts an example implementation of a charge pump configured as a multi-stage charge pump

FIG. 7 illustrates an example of characterizing a charge pump.

FIG. 8 illustrates an example of a charge pump including regulation circuits.

FIG. 9 illustrates an example that includes control circuits, including a pulse counter, connected to an output of charge pump regulation circuits.

FIGS. 10A-B illustrate examples of pulse counting and storage by a pulse counter and register.

FIG. 11 illustrates examples of pulse counts vs output voltage for different charge pumps, including a simulated charge pump.

FIG. 12 illustrates counting pulses of multiple signals and recording multiple counts.

FIGS. 13A-B illustrate example configurations of charge pumps and control circuits.

FIGS. 14A-D illustrate example methods implementing aspects of the present technology.

### DETAILED DESCRIPTION

Techniques are provided for characterizing charge pumps in a manner that is quick, accurate and non-destructive. In a charge pump that uses a control signal consisting of pulses that cause switching (toggling) of charge pump switches, the control signal may be sampled and the number of pulses within a fixed time period may be counted while the charge pump generates a constant current. The number of pulses indicates how hard the pump is working to maintain a given current and may be taken as an indication of charge pump strength (e.g., a larger number of pulses indicates a relatively weak charge pump while a smaller number of pulses indicates a relatively strong charge pump). Counts may be used to identify defective die (e.g., memory die containing one or more defective charge pump), to identify a cause of failure in a failed product and/or to establish how a population of charge pumps compares with a simulation and/or specification so that charge pump design may be modified to better match simulation and/or comply with a specification while efficiently using die area (e.g., without unnecessarily large circuits).

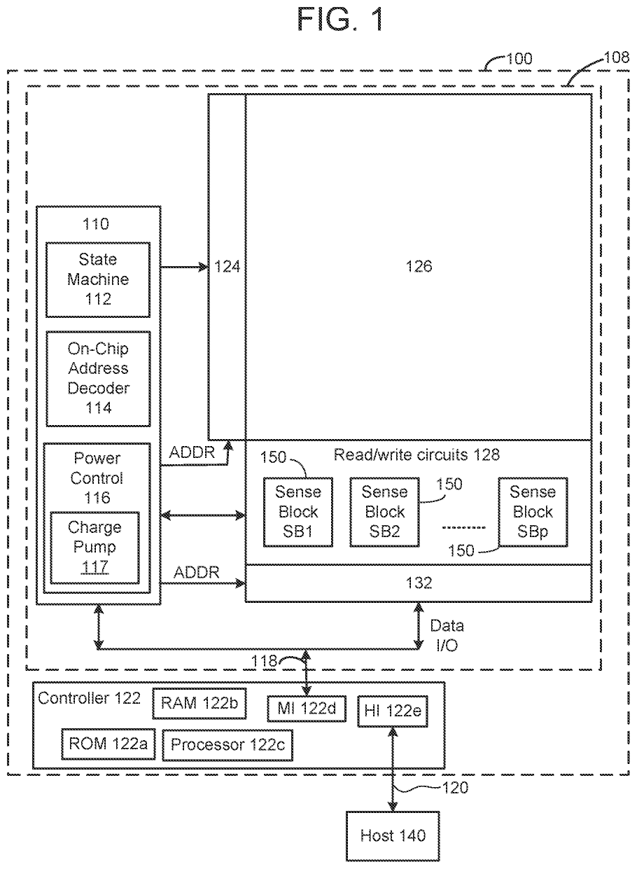

FIG. 1-FIG. 3 describe examples of memory systems that can be used to implement the technology proposed herein. FIG. 1 is a functional block diagram of an example memory system 100. The components depicted in FIG. 1 are electrical circuits. Memory system 100 includes one or more memory dies 108. The one or more memory dies 108 can be complete memory dies or partial memory dies. In one embodiment, each memory die 108 includes a memory structure 126, control circuit 110, and read/write circuits 128. Memory structure 126 is addressable by word lines via a row decoder 124 and by bit lines via a column decoder 132. The read/write/erase circuits 128 include multiple sense blocks 150 including SB1, SB2 . . . , SBp (sensing circuits) and allow a page of memory cells to be read or programmed in parallel. Also, many strings of memory cells can be erased in parallel.

In some systems, a controller 122 is included in the same package (e.g., a removable storage card) as the one or more memory die 108. However, in other systems, the controller can be separated from the memory die 108. In some embodiments the controller will be on a different die than the memory die 108. In some embodiments, one controller 122 will communicate with multiple memory die 108. In other embodiments, each memory die 108 has its own controller. Commands and data are transferred between a host 140 and controller 122 via a data bus 120, and between controller 122 and the one or more memory die 108 via lines 118. In one embodiment, memory die 108 includes a set of input and/or output (I/O) pins that connect to lines 118.

Control circuit 110 cooperates with the read/write circuits 128 to perform memory operations (e.g., write, read, erase and others) on memory structure 126, and includes state machine 112, an on-chip address decoder 114, and a power control circuit 116. In one embodiment, control circuit 110 includes buffers such as registers, ROM fuses and other storage devices for storing default values such as base voltages and other parameters.

The on-chip address decoder 114 provides an address interface between addresses used by host 140 or controller 122 to the hardware address used by the decoders 124 and 132. Power control circuit 116 controls the power and voltages supplied to the word lines, bit lines, and select lines during memory operations. The power control circuit 116 includes voltage circuitry, in one embodiment. Power control circuit 116 includes charge pumps 117 for creating voltages. The sense blocks include bit line drivers. The power control circuit 116 executes under control of the state machine 112, in one embodiment.

State machine 112 and/or controller 122 (or equivalently functioned circuits), in combination with all or a subset of the other circuits depicted in FIG. 1, can be considered a control circuit that performs various functions described herein. The control circuit can include hardware only or a combination of hardware and software (including firmware). For example, a controller programmed by firmware to perform the functions described herein is one example of a control circuit. A control circuit can include a processor, PGA (Programmable Gate Array, FPGA (Field Programmable Gate Array), ASIC (Application Specific Integrated Circuit), integrated circuit or other type of circuit.

The (on-chip or off-chip) controller 122 (which in one embodiment is an electrical circuit) may comprise one or more processors 122c. ROM 122a, RAM 122b, a memory interface (MI) 122d and a host interface (HI) 122e, all of which are interconnected. The storage devices (ROM 122a, RAM 122b) store code (software) such as a set of instructions (including firmware), and one or more processors 122c is/are operable to execute the set of instructions to provide the functionality described herein. Alternatively, or additionally, one or more processors 122c can access code from a storage device in the memory structure, such as a reserved area of memory cells connected to one or more word lines. RAM 122b can be to store data for controller 122, including caching program data (discussed below). Memory interface 122d, in communication with ROM 122a, RAM 122b and processor 122c, is an electrical circuit that provides an electrical interface between controller 122 and one or more memory die 108. For example, memory interface 122d can change the format or timing of signals, provide a buffer, isolate from surges, latch I/O, etc. One or more processors 122c can issue commands to control circuit 110 (or another component of memory die 108) via Memory Interface 122d. Host interface 122e provides an electrical interface with host 140 data bus 120 in order to receive commands, addresses and/or data from host 140 to provide data and/or status to host 140.

In one embodiment, memory structure 126 comprises a three-dimensional memory array of non-volatile memory cells in which multiple memory levels are formed above a single substrate, such as a wafer. The memory structure may comprise any type of non-volatile memory that are monolithically formed in one or more physical levels of arrays of memory cells having an active area disposed above a silicon (or other type of) substrate. In one example, the non-volatile memory cells comprise vertical NAND strings with charge-trapping material.

In another embodiment, memory structure 126 comprises a two-dimensional memory array of non-volatile memory cells. In one example, the non-volatile memory cells are NAND flash memory cells utilizing floating gates. Other types of memory cells (e.g., NOR-type flash memory) can also be used. The exact type of memory array architecture or memory cell included in memory structure 126 is not limited to the examples above.

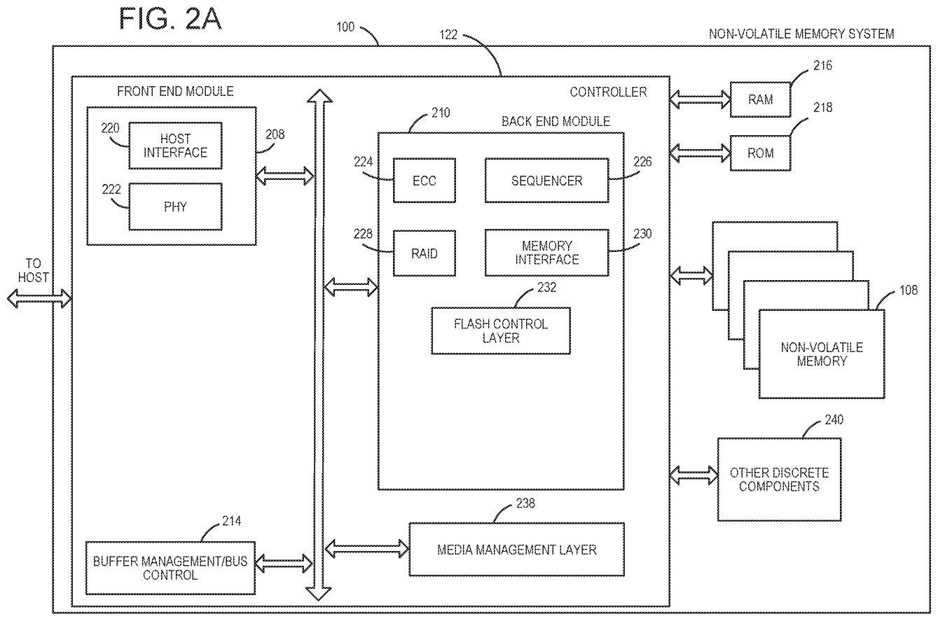

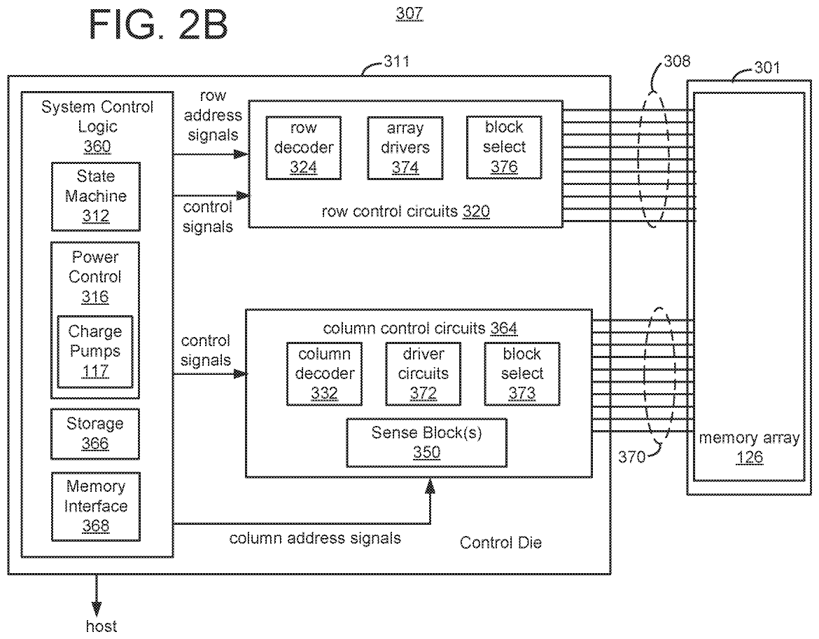

FIG. 2A is a block diagram of example memory system 100, depicting more details of one embodiment of controller 122. The controller in FIG. 2A is a flash memory controller but note that the non-volatile memory die 108 is not limited to flash. Thus, the controller 122 is not limited to the example of a flash memory controller. As used herein, a flash memory controller is a device that manages data stored on flash memory and communicates with a host, such as a computer or electronic device. A flash memory controller can have various functionality in addition to the specific functionality described herein. For example, the flash memory controller can format the flash memory to ensure the memory is operating properly, map out bad flash memory cells, and allocate spare memory cells to be substituted for future failed cells. Some part of the spare cells can be used to hold firmware to operate the flash memory controller and implement other features. In operation, when a host needs to read data from or write data to the flash memory, it will communicate with the flash memory controller. If the host provides a logical address to which data is to be read/written, the flash memory controller can convert the logical address received from the host to a physical address in the flash memory. (Alternatively, the host can provide the physical address). The flash memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

The interface between controller 122 and non-volatile memory die 108 may be any suitable flash interface, such as Toggle Mode 200, 400, or 800. In one embodiment, memory system 100 may be a card-based system, such as a secure digital (SD) or a micro secure digital (micro-SD) card. In an alternate embodiment, memory system 100 may be part of an embedded memory system. For example, the flash memory may be embedded within the host. In other example, memory system 100 can be in the form of a solid state drive (SSD).

In some embodiments, memory system 100 includes a single channel between controller 122 and non-volatile memory die 108, the subject matter described herein is not limited to having a single memory channel. For example, in some memory system architectures, 2, 4, 8 or more channels may exist between the controller and the memory die, depending on controller capabilities. In any of the embodiments described herein, more than a single channel may exist between the controller and the memory die, even if a single channel is shown in the drawings.

As depicted in FIG. 2A, controller 122 includes a front end module 208 that interfaces with a host, a back end module 210 that interfaces with the one or more non-volatile memory die 108, and various other modules that perform functions which will now be described in detail.

The components of controller 122 depicted in FIG. 2A may take the form of a packaged functional hardware unit (e.g., an electrical circuit) designed for use with other components, a portion of a program code (e.g., software or firmware) executable by a (micro) processor or processing circuits that usually performs a particular function of related functions, or a self-contained hardware or software component that interfaces with a larger system, for example. For example, each module may include an application specific integrated circuit (ASIC), a Field Programmable Gate Array (FPGA), a circuit, a digital logic circuit, an analog circuit, a combination of discrete circuits, gates, or any other type of hardware or combination thereof. Alternatively, or in addition, each module may include software stored in a processor readable device (e.g., memory) to program a processor for controller 122 to perform the functions described herein. The architecture depicted in FIG. 2A is one example implementation that may (or may not) use the components of controller 122 depicted in FIG. 1 (i.e., RAM, ROM, processor, interface).

Referring again to modules of the controller 122, a buffer manager/bus control 214 manages buffers in random access memory (RAM) 216 and controls the internal bus arbitration of controller 122. A read only memory (ROM) 218 stores system boot code. Although illustrated in FIG. 2A as located separately from the controller 122, in other embodiments one or both of the RAM 216 and ROM 218 may be located within the controller. In yet other embodiments, portions of RAM and ROM may be located both within the controller 122 and outside the controller. Further, in some implementations, the controller 122, RAM 216, and ROM 218 may be located on separate semiconductor die.

Front end module 208 includes a host interface 220 and a physical layer interface (PHY) 222 that provide the electrical interface with the host or next level storage controller. The choice of the type of host interface 220 can depend on the type of memory being used. Examples of host interfaces 220 include, but are not limited to, SATA, SATA Express, SAS, Fibre Channel, USB, PCIe, and NVMe. The host interface 220 typically facilitates transfer for data, control signals, and timing signals.

Back end module 210 includes an error correction code (ECC) engine 224 that encodes the data bytes received from the host and decodes and error corrects the data bytes read from the non-volatile memory. A command sequencer 226 generates command sequences, such as program and erase command sequences, to be transmitted to non-volatile memory die 108. A RAID (Redundant Array of Independent Dies) module 228 manages generation of RAID parity and recovery of failed data. The RAID parity may be used as an additional level of integrity protection for the data being written into the memory system 100. In some cases, the RAID module 228 may be a part of the ECC engine 224. Note that the RAID parity may be added as an extra die or dies as implied by the common name, but it may also be added within the existing die, e.g., as an extra plane, or extra block, or extra WLs within a block. A memory interface 230 provides the command sequences to non-volatile memory die 108 and receives status information from non-volatile memory die 108. In one embodiment, memory interface 230 may be a double data rate (DDR) interface, such as a Toggle Mode 200, 400, or 800 interface. A flash control layer 232 controls the overall operation of back end module 210.

Additional components of memory system 100 illustrated in FIG. 2A include media management layer 238, which performs wear leveling of memory cells of non-volatile memory die 108. Memory system 100 also includes other discrete components 240, such as external electrical interfaces, external RAM, resistors, capacitors, or other components that may interface with controller 122. In alternative embodiments, one or more of the physical layer interface 222, RAID module 228, media management layer 238 and buffer management/bus controller 214 are optional components that are not necessary in the controller 122.

The Flash Translation Layer (FTL) or Media Management Layer (MML) 238 may be integrated as part of the flash management that may handle flash errors and interfacing with the host. In particular, MML may be a module in flash management and may be responsible for the internals of NAND management. In particular, the MML 238 may include an algorithm in the memory device firmware which translates writes from the host into writes to the memory structure 126 of memory die 108. The MML 238 may be needed because: 1) the memory may have limited endurance; 2) the memory structure 126 may only be written in multiples of pages; and/or 3) the memory structure 126 may not be written unless it is erased as a block (or a tier within a block in some embodiments). The MML 238 understands these potential limitations of the memory structure 126 which may not be visible to the host. Accordingly, the MML 238 attempts to translate the writes from host into writes into the memory structure 126.

Controller 122 may interface with one or more memory dies 108. In one embodiment, controller 122 and multiple memory dies (together comprising memory system 100) implement a solid state drive (SSD), which can emulate, replace or be used instead of a hard disk drive inside a host, as a NAS device, in a laptop, in a tablet, in a server, etc. Additionally, the SSD need not be made to work as a hard drive.

Some embodiments of a non-volatile storage system will include one memory die 108 connected to one controller 122. However, other embodiments may include multiple memory die 108 in communication with one or more controllers 122. In one example, the multiple memory die can be grouped into a set of memory packages. Each memory package includes one or more memory die in communication with controller 122. In one embodiment, a memory package includes a printed circuit board (or similar structure) with one or more memory die mounted thereon. In some embodiments, a memory package can include molding material to encase the memory dies of the memory package. In some embodiments, controller 122 is physically separate from any of the memory packages.

In one embodiment, the control circuit(s) (e.g., control circuits 110) are formed on a first die, referred to as a control die, and the memory array (e.g., memory structure 126) is formed on a second die, referred to as a memory die. For example, some or all control circuits (e.g., control circuit 110, row decoder 124, column decoder 132, and read/write circuits 128) associated with a memory may be formed on the same control die. A control die may be bonded to one or more corresponding memory die to form an integrated memory assembly. The control die and the memory die may have bond pads arranged for electrical connection to each other. Bond pads of the control die and the memory die may be aligned and bonded together by any of a variety of bonding techniques, depending in part on bond pad size and bond pad spacing (i.e., bond pad pitch). In some embodiments, the bond pads are bonded directly to each other, without solder or other added material, in a so-called Cu-to-Cu bonding process. In some examples, dies are bonded in a one-to-one arrangement (e.g., one control die to one memory die). In some examples, there may be more than one control die and/or more than one memory die in an integrated memory assembly. In some embodiments, an integrated memory assembly includes a stack of multiple control die and/or multiple memory die. In some embodiments, the control die is connected to, or otherwise in communication with, a memory controller. For example, a memory controller may receive data to be programmed into a memory array. The memory controller will forward that data to the control die so that the control die can program that data into the memory array on the memory die.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 307. One or more integrated memory assemblies 307 may be used in a memory package in memory system 100. The integrated memory assembly 307 includes two types of semiconductor die (or more succinctly, “die”). Memory die 301 includes memory structure 126

Control die 311 includes column control circuits 364, row control circuits 320 and system control logic 360 (including state machine 312, power control module 316 (including charge pumps 117), storage 366, and memory interface 368). In some embodiments, control die 311 is configured to connect to the memory array 126 in the memory die 301. FIG. 2B shows an example of the peripheral circuits, including control circuits, formed in a peripheral circuit or control die 311 coupled to memory array 126 formed in memory die 301. System control logic 360, row control circuits 320, and column control circuits 364 are located in control die 311. In some embodiments, all or a portion of the column control circuits 364 and all or a portion of the row control circuits 320 are located on the memory die 301. In some embodiments, some of the circuits in the system control logic 360 is located on the on the memory die 301.

System control logic 360, row control circuits 320, and column control circuits 364 may be formed by a common process (e.g., CMOS process), so that adding elements and functionalities, such as ECC, more typically found on a memory controller 102 may require few or no additional process steps (i.e., the same process steps used to fabricate memory controller 102 may also be used to fabricate system control logic 360, row control circuits 320, and column control circuits 364). Thus, while moving such circuits from a die such as memory die 301 may reduce the number of steps needed to fabricate such a die, adding such circuits to a die such as control die 311 may not require many additional process steps.

FIG. 2B shows column control circuits 364 including sense block(s) 350 on the control die 311 coupled to memory array 126 on the memory die 301 through electrical paths 370. For example, electrical paths 370 may provide electrical connection between column decoder 332, driver circuits 372, and block select 373 and bit lines of memory array (or memory structure) 126. Electrical paths may extend from column control circuits 364 in control die 311 through pads on control die 311 that are bonded to corresponding pads of the memory die 301, which are connected to bit lines of memory structure 126. Each bit line of memory structure 126 may have a corresponding electrical path in electrical paths 370, including a pair of bond pads, which connects to column control circuits 364. Similarly, row control circuits 320, including row decoder 324, array drivers 374, and block select 376 are coupled to memory array 126 through electrical paths 308. Each of electrical path 308 may correspond to a word line, dummy word line, or select gate line. Additional electrical paths may also be provided between control die 311 and memory die 301.

In some embodiments, there is more than one control die 311 and/or more than one memory die 301 in an integrated memory assembly 307. In some embodiments, the integrated memory assembly 307 includes a stack of multiple control die 311 and multiple memory dies 301. In some embodiments, each control die 311 is affixed (e.g., bonded) to at least one of the memory dies 301.

The exact type of memory array architecture or memory cell included in memory structure 126 is not limited to the examples above. Many different types of memory array architectures or memory cell technologies can be used to form memory structure 126. No particular non-volatile memory technology is required for purposes of the new claimed embodiments proposed herein. Other examples of suitable technologies for memory cells of the memory structure 126 include ReRAM memories, magnetoresistive memory (e.g., MRAM, Spin Transfer Torque MRAM, Spin Orbit Torque MRAM), phase change memory (e.g., PCM), and the like. Examples of suitable technologies for architectures of memory structure 126 include two dimensional arrays, three dimensional arrays, cross-point arrays, stacked two dimensional arrays, vertical bit line arrays, and the like.

One example of a ReRAM, or PCMRAM, cross point memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse but includes a (continuous or non-continuous) vibration or burst of sound, current, voltage light, or other wave.

A person of ordinary skill in the art will recognize that the technology described herein is not limited to a single specific memory structure, but covers many relevant memory structures within the spirit and scope of the technology as described herein and as understood by one of ordinary skill in the art.

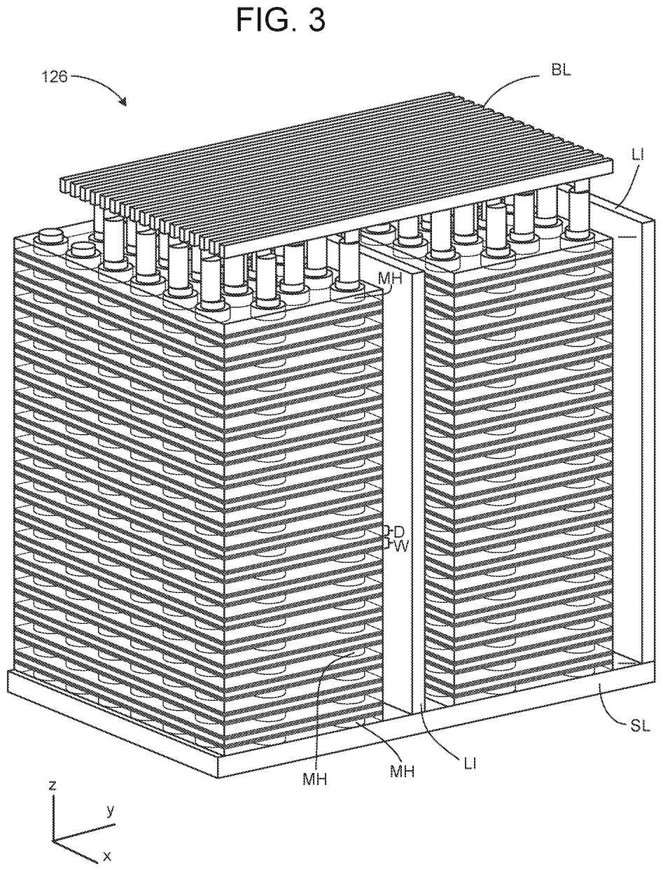

FIG. 3 is a perspective view of a portion of one example embodiment of a monolithic three dimensional memory array that can comprise memory structure 126, which includes a plurality non-volatile memory cells. For example, FIG. 3 shows a portion of one block of memory. The structure depicted includes a set of bit lines BL positioned above a stack of alternating layers of dielectric material and conductive material on a substrate. For example, one of the dielectric layers is marked as D and one of the conductive layers (also called word line layers) is marked as W. The number of alternating dielectric layers and conductive layers can vary based on specific implementation requirements. One set of embodiments includes between 108-300 alternating dielectric layers and conductive layers. One example embodiment includes 96 data word line layers, 8 select layers, 6 dummy word line layers and 110 dielectric layers. More or less than 108-300 layers can also be used. Data word line layers have data memory cells. Dummy word line layers have dummy memory cells. As will be explained below, the alternating dielectric layers and conductive layers are divided into “fingers” in regions that are separated by local interconnects LI. FIG. 3 shows two regions, each with respective NAND strings, and two local interconnects LI. Below the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data.

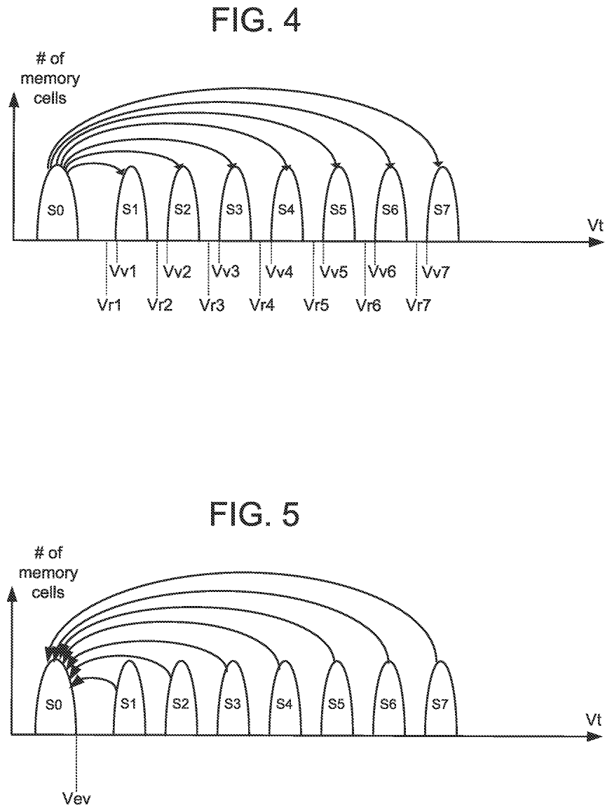

FIG. 4 shows threshold voltage distributions for eight data states, S0 to S7, corresponding to three bits of data per cell (Three Level Cell, or TLC). Also shown are seven read reference voltages, Vr1, Vr2, Vr3, Vr4, Vr5, Vr6, and Vr7 for reading data from memory cells. By testing (e.g., performing sense operations) whether the threshold voltage of a given memory cell is above or below the seven read reference voltages, the system can determine what data state (i.e., S0, S1, S2, S3, . . . ) a memory cell is in.

FIG. 4 also shows seven verify reference voltages, Vv1, Vv2, Vv3, Vv4, Vv5, Vv6, and Vv7 used in read verify steps during a programming operation. When programming memory cells to data state S1, the system will test whether those memory cells have a threshold voltage greater than or equal to Vv1. When programming memory cells to data state S2, the system will test whether the memory cells have threshold voltages greater than or equal to Vv2. When programming memory cells to data state S3, the system will determine whether memory cells have their threshold voltage greater than or equal to Vv3. When programming memory cells to data state S4, the system will test whether those memory cells have a threshold voltage greater than or equal to Vv4. When programming memory cells to data state S5, the system will test whether those memory cells have a threshold voltage greater than or equal to Vv5. When programming memory cells to data state S6, the system will test whether those memory cells have a threshold voltage greater than or equal to Vv6. When programming memory cells to data state S7, the system will test whether those memory cells have a threshold voltage greater than or equal to Vv7. FIG. 5A also shows Vev, which is a voltage level to test whether a memory cell has been properly erased (e.g., whether a memory cell is in the S0 data state).

In general, during sensing of verify and read operations, the selected word line is connected to a voltage (one example of a reference signal or read voltage), a level of which is specified for each read operation (e.g., see read compare levels Vr1, Vr2, Vr3, Vr4, Vr5, Vr6, and Vr7, of FIG. 5) or verify operation (e.g. see verify target levels Vv1, Vv2, Vv3, Vv4, Vv5, Vv6, and Vv7 of FIG. 5A) in order to sense whether a threshold voltage of the concerned memory cell has reached such level. After applying the read voltage to the word line, the conduction current of the memory cell is measured to determine whether the memory cell turned on (conducted current) in response to the voltage applied to the word line. If the conduction current is measured to be greater than a certain value (e.g., Isense), then it is assumed that the memory cell turned on and the voltage applied to the word line is greater than the threshold voltage of the memory cell. If the conduction current is not measured to be greater than the certain value, then it is assumed that the memory cell did not turn on and the voltage applied to the word line is not greater than the threshold voltage of the memory cell. During a read or verify process, the unselected data memory cells are provided with one or more read pass voltages (also referred to as bypass voltages) at their control gates so that these data memory cells will operate as pass gates (e.g., conducting current regardless of whether they are programmed or erased), select gates of selected NAND strings are provided with sufficient voltage (e.g., select voltages via select lines) to make corresponding select transistors conductive (“turn on”) and dummy memory cells of selected NAND strings are provided with sufficient voltage (e.g., dummy word line voltage via dummy word lines) to make corresponding dummy memory cells conductive.

FIG. 5 shows an example of an erase operation in which charge is removed from memory cells of threshold voltage distributions for seven data states, S1 to S7, which results in all programmed memory cells being in erased state S0. Also shown is erase verify voltage, Vev for verifying memory cells are in state S0. In an example, a high voltage (erase voltage) is applied to word lines of a block to erase memory cells. For example, 20 volts may be used as an erase voltage while lower voltages may be used to program and read memory cells. Programming memory cells may use voltage pulses of different voltages and reading may apply different read voltages and read pass voltages to word lines. Additional voltages may be applied to dummy word lines, select lines and other components. Thus, a range of voltages may be used in various access operations (read, write and erase) directed to memory cells. In general, such voltages are not all directly supplied to a memory die (e.g., memory die 108) and may be generated on-chip. For example, memory die 108 may receive a supply voltage (e.g., 1.8 volts or 3.0 volts) and may generate different voltages (e.g., erase voltage, read voltages, program voltages) from the supply voltage using appropriate power circuits. An example of a circuit that may be used to generate a relatively high voltage (e.g., erase voltage) from a lower supply voltage is a charge pump.

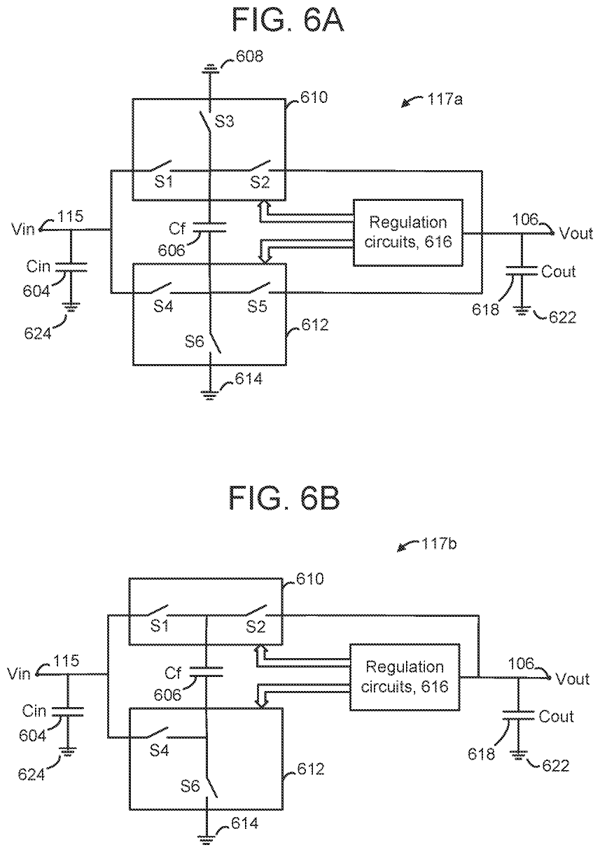

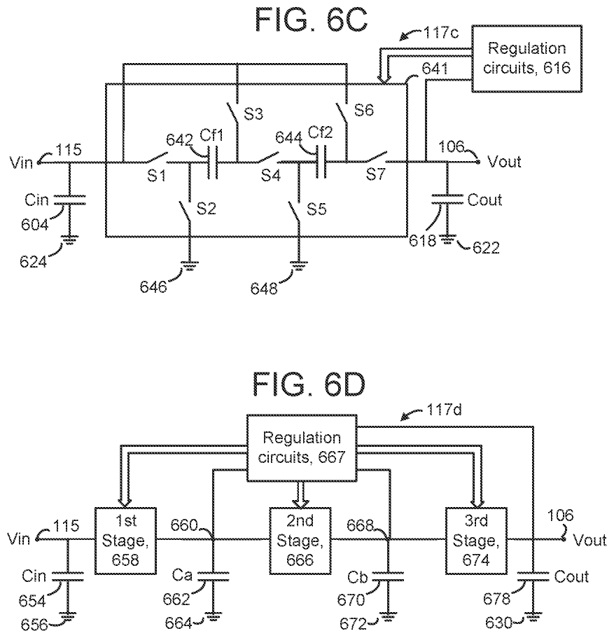

FIGS. 6A to 6D provide example configurations of a charge pump (e.g., charge pump 117 in FIGS. 1 and 2B). A charge pump can use a capacitor to transfer charge from an input node to an output node.

FIG. 6A depicts an example implementation of the charge pump 117 configured as a single-stage charge pump 117a. A charge pump generally refers to a switching voltage converter that employs an intermediate capacitive storage element which is sometimes referred to as a flying capacitor or a charge transfer capacitor. One or more capacitors can be used. Moreover, a charge pump can include multiple stages connected in series to obtain special features such as a high output voltage and a greater range of output voltages. A charge pump can be constructed or configured for providing voltage conversion for applications including: multiplier, divider, inverter and follower. The principles discussed herein can be applied to one or more stages, and to one or more capacitors in a stage. The charge pump 117a is a generalized embodiment which can be controlled for multiplier, divider, inverter and follower applications. The charge pump 117a includes an input node 115 at which an input voltage (Vin) is applied. For example, Vin may be equal to a fixed power supply voltage sometimes referred to as Vdd or Vcc in a semiconductor chip. Or, Vin may be a clamped voltage which is lower than the power supply voltage. Charge from the voltage is maintained in an input capacitor Cin 604 which is connected to a ground node 624.

A first set of switches 610 and a second set of switches 612 are controlled by regulation circuits 616 to transfer charge from the input node 115 to a capacitor Cf 606, and from Cf 606 to an output node 106. Vout is a resulting voltage at the output node 106 and can be greater than or less than Vin. The output node is coupled to an output capacitor Cout 618, which is connected to a ground node 622. The first set of switches 610 includes switches S1, S2 and S3 which are star-connected to one terminal (such as the top conductor) of Cf. The switches may be MOSFETs, bipolar junction transistors, relay switches, or the like. S1 connects the top conductor of Cf 606 to the input node 115 to receive a charge from Vin. S2 connects the top conductor of Cf 606 to the output node 106 to transfer its charge to the output node. S3 connects the top conductor of Cf 606 to a ground node 608. Similarly, the second set of switches 612 includes switches S4, S5 and S6 which are star-connected to another terminal (such as the bottom conductor) of Cf 606. S4 connects the bottom conductor of Cf 606 to the input node 115 to receive a charge from Vin. S5 connects the bottom conductor of Cf 606 to the output node 106 to transfer its charge to the output node. S6 connects the bottom conductor of Cf 606 to a ground node 614.

FIG. 6B depicts an example implementation of the charge pump 117 configured as a voltage multiplier 117b. A voltage multiplier, or step-up charge pump, in general, provides Vout>Vin. In this configuration, the voltage multiplier provides 2×Vin>Vout>Vin, and the switches S3 and S5 of FIG. 6A are not needed. In a charging phase, the regulation circuits 616 provides the switches with appropriate control signals so that S1 is closed, e.g., conductive, and S2 is open, e.g., non-conductive, so that Cf 606 is charged via S1. Further, S4 is open and S6 is closed so that the bottom conductor of Cf 606 is connected to the ground node 614. In a discharging phase, S1 is open and S2 is closed, so that Cf 606 is discharged, at least in part, to the output node 106 via S2. Further, S4 is closed and S6 is open.

FIG. 6C depicts an example implementation of the charge pump 117 configured as a single-stage, multi-capacitor charge pump 117c. In this example, multiple flying capacitors are provided in a single stage. While two capacitors are provided as an example, more than two may be used. There are many possible charge pump configurations with multiple flying capacitors. The charge pump 117c is configured as a voltage multiplier in which Vout≈3×Vin. Capacitors Cf1 642 and Cf2 644 are provided. A set of switches 641 includes switches S1 to S7. S2 and S5 are connected to ground nodes 646 and 648, respectively. During a charging phase, switches S2, S3, S5, and S6 are closed, while S1, S4 and S7 are open, so that both flying capacitors Cf1 and Cf2 are connected in parallel and charged to the input voltage. During a discharging phase, switches S1, S4 and S7 are closed, and S2, S3, S5 and S6 are open, so that the flying capacitors are connected in series between the input node 115 and the output node 106. This effectively creates an output voltage of approximately three times the input voltage.

The use of multiple flying capacitors in a single stage can provide a ratio between Vout and Vin, e.g., Vout=1.5×Vin, 3×Vin, etc., or Vout=½×Vin, ⅓×Vin, etc. For greater flexibility, a multi-stage charge pump, such as described below, can be used.

FIG. 6D depicts an example implementation of the charge pump 117 configured as a multi-stage charge pump 117d. Vin is provided at input node 115 so that Vout is obtained at an output node 106. As an example, three stages 658, 666 and 674 are provided. Two or more stages may be used. Each stage can include switches and one or more flying capacitors as discussed previously, for example. At the input, a capacitor Cin 654 is connected at one of its conductive layers to a ground node 656. At a node 660 which is between the first stage 658 and the second stage 666, a capacitor Ca 662 is connected at one of its conductive layers to a ground node 664. At a node 668 which is between the second stage 666 and the third stage 674, a capacitor Cb 670 is connected at one of its conductive layers to a ground node 672. Finally, at the output node 106, an output capacitor Cout 678 is connected at one of its conductive layers to a ground node 630. A multi-stage charge pump can provide greater flexibility in terms of providing a greater range of output voltages. Further, each stage can include one or more capacitors to provide even greater flexibility.

The multi-stage charge pump 117d is operated under the control of regulation circuits 667 which controls switching in each stage. Note that it is also possible to provide regulation circuits in each stage, additionally or alternatively. Charge is transferred from the input node 115 of the first stage to a flying capacitor (not shown) in the first stage 658, and from the flying capacitor of the first stage to the node 660. Charge is then transferred from the node 660 of the second stage to a flying capacitor (not shown) in the second stage, and from the flying capacitor of the second stage to the node 668. Charge is then transferred from the node 668 to a flying capacitor (not shown) in the third stage, and from the flying capacitor of the third stage to the output node 106, assuming there are no further stages.

Example charge pumps 117a-d of FIGS. 6A-D have a charging phase and a discharging phase. Switches (e.g., switches S1-7) are switched, or toggled, according to phase by control signals from regulation circuits 616, 667. For example, regulation circuits 616, 667 may send a series of voltage pulses to cause switches S1-7 to alternate on/off or off/on and thereby provide an output current at output node 106. Regulation circuits 616 are connected to output node 106 to respond to changes in voltage, Vout, at output node 106 (e.g., Vout may be controlled by regulation circuits 616 in a feedback loop). Regulation circuits 667 are connected to output nodes 660, 668 and 106 of each switching stage to respond to changes in respective stage output voltages (e.g., multiple feedback loops). For example, when regulation circuits 667 determine that output voltage, Vout, is below a setpoint, regulation circuits 616 may send pulses to generate an output current, which causes Vout to increase as output capacitor, Cout, charges up. When regulation circuits 667 determine that output voltage, Vout, is above the setpoint, regulation circuits 616 may stop sending pulses, which may cause output capacitor. Cout, to discharge. In a given phase some switches may be open (off) and other switches may be closed (on) according to the signals they receive (e.g., some may receive an inverted signal) and/or switch configuration (e.g., some normally-on and some normally-off)

Multiple capacitors are used in each of the example implementations of charge pump 117 illustrated in FIGS. 6A-D. The capacitors may be relatively large components so that charge pumps may occupy significant area on a die (e.g., a memory die). For example, charge pump 117 of FIG. 1 may occupy a large part of the area of power control circuit 116 (e.g., more than half), which may represent a significant area.

Because charge pumps are large, redundant charge pumps may not be provided and successful operation of charge pumps may be of high importance (e.g., compared with components that have redundant units available for replacement). For example, a memory die may include several charge pumps and failure of any single charge pump may cause die failure and/or sub-optimal characteristics may cause the memory die to be classified and priced accordingly. Charge pumps may have a range of characteristics (e.g., due to process variations across a wafer, from wafer to wafer, or otherwise). Simulation and testing may be used to ensure that substantially all (e.g., more than 99.99%) of charge pumps meet a specification (e.g., are capable of providing a specified current at a specified voltage). Simulation may not be very accurate (e.g., some assumptions used in a simulation model may be based on worst-case scenarios and may not align with actual values across a large population). Testing physical samples provides another approach to ensuring charge pumps meet a specification.

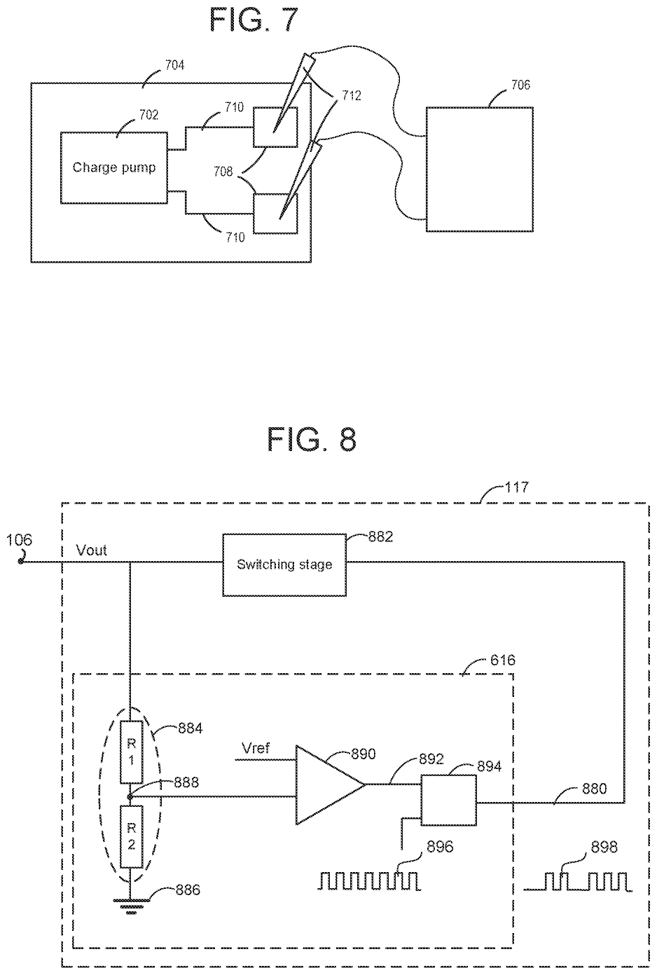

FIG. 7 shows an example of testing a charge pump 702 located on a portion of a die 704 (e.g., one of a plurality of charge pumps located on a memory die such as memory die 108 or a control die such as control die 311). In order to connect test equipment 706 (e.g., a parameter analyzer or other test equipment) to charge pump 702, it may be necessary to form pads 708 on a surface of die 704. Pads 708 are connected to charge pump 702 by wires 710 (e.g., traces) which may have significant resistance that may affect measurement by test equipment 706. Pads 708 are accessible and may be contacted by probes 712, which are connected to test equipment 706 (while two pads 708 and two probes 712 are shown, the number of pads and probes may be different, e.g., one, three, four or more). Pads 708 may not be provided in a die design and may be added as a customized modification after die fabrication. For example, Focused Ion Beam (FIB) deposition may be used to form pads 708. Testing according to the example shown in FIG. 7 may take significant time (e.g., to form pads, manually connect probes to pads and run testing). Such testing may last weeks or months and may require significant resources including FIB equipment and testing equipment. Such time-consuming, resource-intensive testing may be suitable for a few samples of a new product to ensure that charge pumps meet a minimum standard and is not easily scalable for testing a large population of dies.

Testing a small sample may not adequately characterize a large population. Accurate characterization of a large population of charge pumps (e.g., multiple charge pumps per memory die across many dies per wafer and large numbers of wafers) may be challenging. Without accurate characterization, charge pump design may be limited by simulation with some limited testing for verification. While charge pumps may be oversized or overengineered to ensure that they meet a specification, this may be unnecessarily wasteful of valuable area on a memory die.

In examples of the present technology, a large population of charge pumps may be individually characterized in a manner that is rapid, accurate and non-destructive. Aspects of the present technology provide technical solutions to the problems of accurately characterizing charge pumps, for example, so that charge pumps can be sized appropriately to meet a specification without using space unnecessarily. Aspects of the present technology may also be used for testing to identify defective products (e.g., factory testing prior to sale) and for failure analysis purposes (e.g., testing of one or more charge pump of a failed memory die to determine if the charge pump(s) meet a specification).

Aspects of the present technology include control circuits that are configured to use one or more control signal of a charge pump to characterize the charge pump. For example, where such a signal includes a number of pulses (e.g., clock pulses) the number of such pulses may be counted over a period of time and this number may characterize charge pump. Counting pulses may be performed on-chip (e.g., by control circuits on a memory die or a control die) without the need for specialized test equipment and without post-production modification of a die (e.g., without adding pads). Pulse counts may be recorded and maintained for some or all charge pumps of a die and may be sent from the die (e.g., to a test unit that is connected as a host during testing or failure analysis) in response to a command. By collecting charge pump data over a large population, the charge pumps of the population may be accurately characterized, which may facilitate design of charge pumps (e.g., reduction of charge pump size compared with an overengineering approach).

FIG. 8 shows an example implementation of regulation circuits 616 of charge pump 117 (e.g., any one of charge pumps 117a, 117b or 117d). Regulation circuits 616 have an output channel 880 that connects to switches of switching stage 882 (e.g., one or more traces leading to individual switches S1, S2, S3 . . . of a switching stage). An output signal of regulation circuits 616 may control switching (toggling) of switches of switching stage 882 (e.g. pulses toggling switches) to maintain output voltage, Vout, of charge pump 117.

Regulation circuits 616 include a voltage divider 884, which is connected between output node 106 and a ground node 886. Voltage divider 884 includes two resistors, R1 and R2, which are selected to provide a voltage at an intermediate node 888 that is a predetermined fraction of output voltage Vout (e.g., ½, ¼, 1/10, or other fraction). The voltage at node 888 follows Vout and is connected to a first input of a comparator 890. A reference voltage, Vref, is applied to a second input of comparator 890 (e.g., comparator 890 has a first input connected to output node 106 through voltage divider 884 and a second input connected to reference voltage, Vref). Comparator 890 is configured to provide a comparator output signal 892 indicating when output voltage Vout at output node 106 is below a predetermined voltage (e.g., Vref may be set to cause switching of comparator output signal 892 of comparator 890 when Vout is at the predetermined voltage). Comparator output signal 892 is provided to switch 894 (e.g., on a first switch input), which also receives a clock signal 896 (e.g., on a second switch input). Switch 894 provides an output signal 898 on output channel 880 that depends on its inputs. For example, when comparator output signal 892 indicates that Vout is below the predetermined voltage, switch 894 is configured to provide pulses of a (e.g., passing through pulses of clock signal 896) on output channel 880, which causes switching of switching stage 882 and generation of an output current. When comparator output signal 892 indicates that Vout is above the predetermined voltage, switch 894 is configured not to provide pulses on output channel 880 so that no switching occurs and no output current is generated by switching stage 882. As a result, output signal 898 includes fewer pulses than clock signal 896 corresponding to times when Vout was above the predetermined voltage.

While FIG. 8 provides a relatively simple (single stage) illustration of a regulation circuit 616 controlling a switching stage of a charge pump, the present technology is not limited to such examples and may be applied to a wide range of single-stage and multi-stage charge pumps that use pulses to switch (toggle) switches of a charge pump.

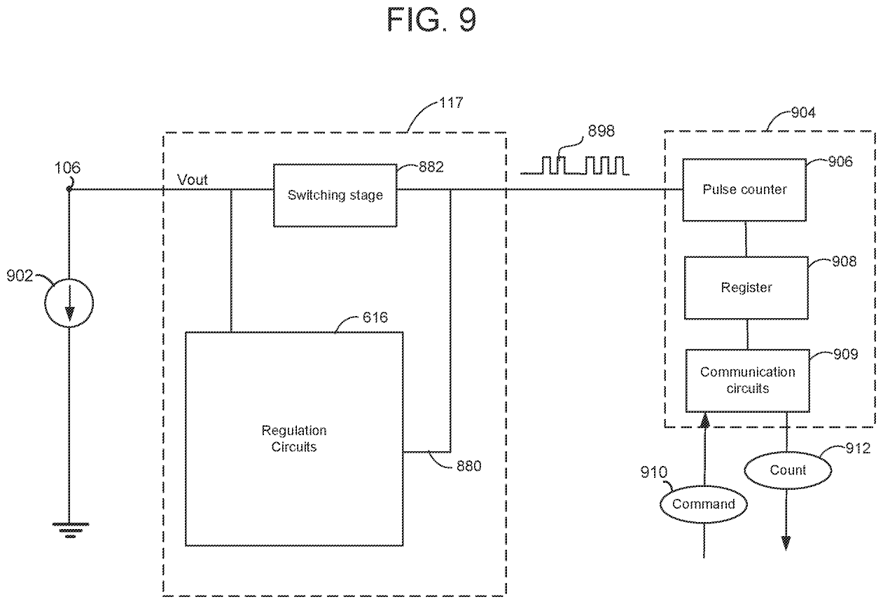

FIG. 9 illustrates an example of charge pump 117 connected to control circuits 904, which implement aspects of the present technology. Charge pump 117 is configured as previously described with respect to FIG. 8, with regulation circuits 616 generating a control signal, output signal 898, which is provided via output channel 880 to toggle switches of switching stage 882 based on output voltage, Vout. In the example of FIG. 9, output node 106 is connected to constant current source 902 so that the current through output node 106 (current generated by charge pump 117) is a known constant current. For example, constant current source 902 may be a calibrated current source that is known to provide 100 mA, 150 mA, 250 mA or other predetermined current). Such a current source may be formed on-chip (e.g., using a current mirror).

Output channel 880 is connected to control circuits 904 so that output signal 898 from regulation circuits 616 is sent to control circuits 904. Control circuits 904 include a pulse counter 906, a register 908 and communication circuits 909. Pulse counter 906 may be configured to count the number of pulses received over a predetermined period of time during operation of charge pump 117 (e.g., while supplying a predetermined, calibrated current via constant current source 902). For example, pulse counter 906 may generate a count of pulses that is output as a digital value.

Pulse counter 906 is connected to register 908, which may record the digital value output by pulse counter 906 (e.g., record the count of the number of pulses sent to the switches of switching stage 882 in a predetermined time period). Register 908 may be readable in response to a command, e.g., readable by communication circuits 909. Register 908 and communication circuits 909 may be implemented by any suitable circuits (e.g., control circuits 110, system control logic 360 or otherwise).

FIG. 9 shows control circuits 904 receiving a command 910 (e.g., from a testing unit connected to control circuits 904). In response to command 910, communication circuits 909 send the count 912 of the number of pulses (e.g., to the testing unit). In an example, a testing unit may be connected to control circuits 904 through a memory controller (e.g., through controller 122) via a host interface (e.g., host data bus 120). In this way, a finished product (e.g., a memory system that includes one or more nonvolatile memory dies and a memory controller with a host interface) may be tested without modification (e.g., without adding pads or otherwise physically modifying the product). Such testing is suitable for large scale use (e.g., final testing of products in a factory prior to shipment). Using this approach, some or all charge pumps on some or all dies (e.g., memory dies) may be tested to identify failures and/or to categorize dies according to performance (e.g., to bin dies as high-performing to low-performing). Collecting data over a significant population may provide accurate characterization of charge pumps, which may allow engineering decisions (e.g., sizing of capacitors in a product design) to be made with confidence without unnecessary overengineering.

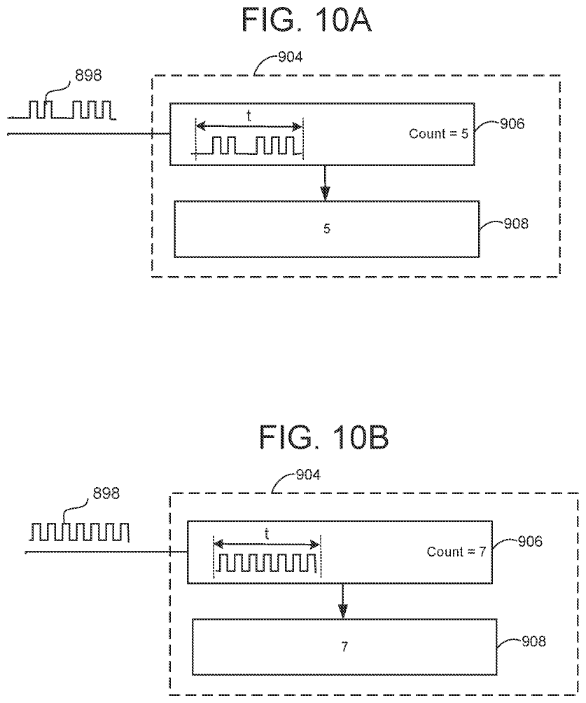

FIGS. 10A-B illustrate operation of pulse counter 906 with different control signals (e.g. control signals generated by regulation circuit 616 to control switching of switches of a charge pump). In the example of FIG. 10A, control circuits 904 receive output signal 898 from regulation circuits 616 as shown in FIG. 9. Pulse counter 906 counts pulses in output signal 898 over a predetermined time period, t. In the example of FIG. 10A, five (5) pulses are received in time t and this count is sent to register 908, where it is stored.

In the example of FIG. 10B, output signal 898 includes more pulses within the time t. In this case, the number of pulses counted is seven (7). The count is sent to register 908 where it is recorded. (The above example is for illustration purposes and the time, t, and counts obtained during actual testing may be greater so that the count accurately reflects average switching frequency over a longer period.)

The number of pulses counted within a given time period (e.g., time t) is equal to the number of times switches of charge pump 117 toggle within the time period. A charge pump may require more switching operations (more frequent switching) for various reasons. For example, more switching operations may be used to output a higher current than to output a lower current and more switching operations may be used to maintain a higher output voltage than to maintain a lower output voltage. In order to accurately characterize a charge pump, different loads may be connected to the output of the charge pump (e.g., different constant current sources) to test the charge pump using different output currents. For a given load/current, a charge pump may be tested over a range of output voltages.

Some charge pumps may require more switching operations than others while providing the same output because of differences during die fabrication. For example, differences in capacitance of capacitors, resistances of electrical connections, differences in switches (e.g., transistors), differences in parasitic capacitance and parasitic resistance and/or other differences may affect charge pump performance from charge pump to charge pump (e.g., on the same die and/or from die-to-die). Such differences may cause differences in switching frequency, which may be quantified by counting pulses of a control signal (e.g., output signal 898 over a predetermined period). For a given output current and voltage, a charge pump that has a higher switching frequency may be considered weaker than a charge pump that has a lower switching frequency. For example, weaker charge pump may require more switching operations because less charge is transferred in each switching cycle. A weak charge pump may not meet a specification, for example, because it may not be able to achieve a specified output current and voltage even when operating at maximum switching frequency. The present technology allows such weak charge pumps to be identified and appropriate action to be taken. For example, a die may be marked as defective and may be discarded if one or more charge pumps are sufficiently weak (e.g., if a count of pulses in a control signal exceeds a limit) and/or may be binned as low-performing (e.g., if a count of pulses in a control signal is in a corresponding range). In some cases, clock frequency may be increased or other measures may be implemented to increase output current of a charge pump that is found to be weak.

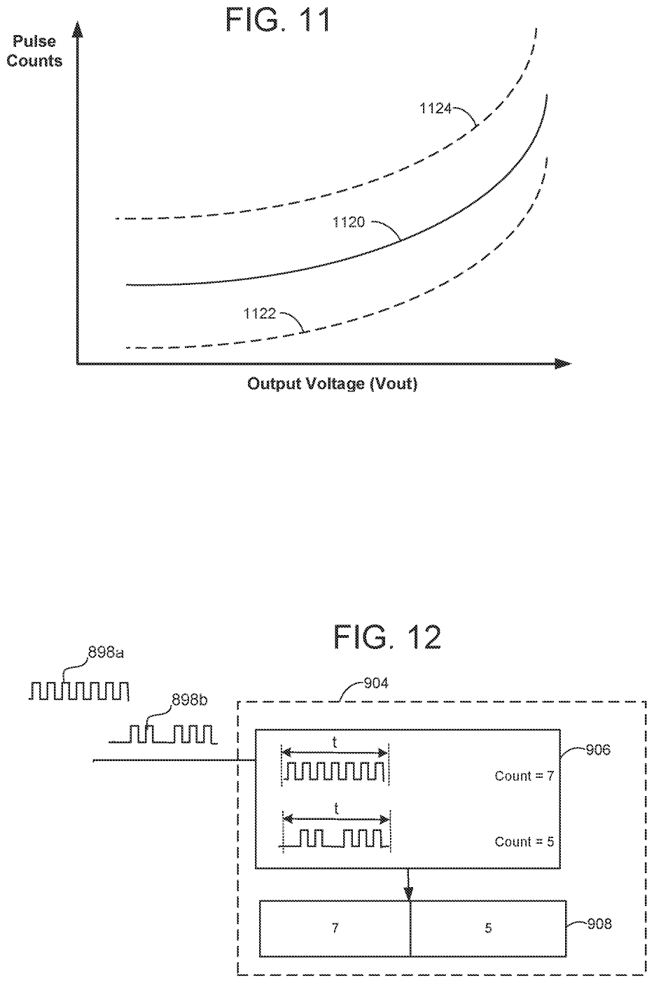

FIG. 11 shows an example of pulse counts observed (e.g., by pulse counter 906) for different charge pumps providing the same output current over a range of voltages (e.g., charge pump 117 connected to constant current source 902). The middle line 1120 shows data from simulation of a charge pump as designed. The lower line 1122 corresponds to charge pumps that are stronger than indicated by simulation (e.g., can achieve a given output current and voltage using fewer switching operations). In some cases, where a population of charge pumps is found to be significantly stronger than simulation indicates, charge pumps may be redesigned (e.g., with smaller capacitors) to make physical charge pumps perform closer to simulated charge pumps and avoid overengineering (e.g., avoid unnecessarily large capacitors). The upper line 1124 corresponds to charge pumps that are weaker than indicated by simulation (e.g., requiring more switching operations to achieve a given output current and voltage). In some cases, where a population of charge pumps are found to be significantly weaker than simulation indicates, charge pumps may be redesigned to make physical charge pumps perform closer to simulated charge pumps (e.g., to meet a specification).

While the examples of FIGS. 10A-B showed pulse counter 906 counting pulses of a single sample and register 980 storing a single result, the present technology extends to circuits counting pulses of multiple samples and storing corresponding results.

FIG. 12 shows an example of control circuits 904 receiving two examples of a control signal, output signal 898 (designated as 898a and 898b), both of which are sent to pulse counter 906 which counts pulses of both control signals, obtaining counts of 7 and 5 respectively. These counts are sent to register 980, which stores both counts. Multiple control signals may be counted in parallel or in series. For example, control signal 898a-b may be from the same charge pump under different conditions (e.g., different current and/or load) or may be from different charge pumps. While the example of FIG. 12 shows two control signals, a pulse counter may be applied to any number of control signals and a register may be configured to hold any number of counts (e.g., multiple additional counts corresponding to different current and voltage for one or more additional charge pumps).

Charge pumps may have dedicated control circuits (e.g., each charge pump having a dedicated pulse counter and register) or control circuits may be shared between two or more charge pumps (e.g., a single pulse counter may count pulses from two or more charge pumps and the counts may be stored in a single register).

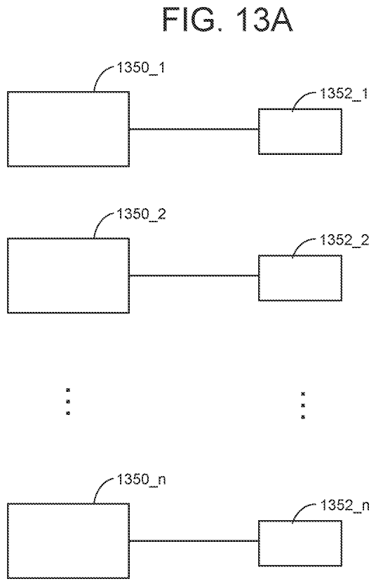

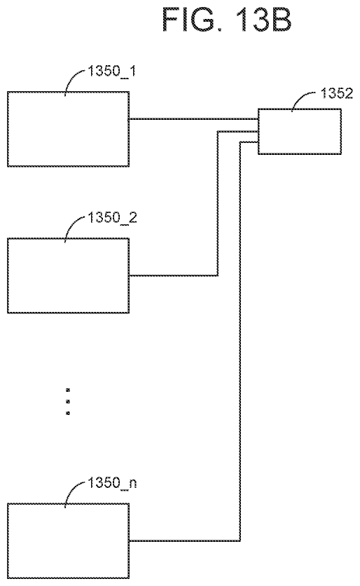

FIG. 13A illustrates a first embodiment that includes a plurality of charge pumps (n charge pumps), 1350_1, 1350_2 . . . 1350_n, which may be formed on the same die. Each charge pump has dedicated control circuits. For example, charge pump 1350_1 is connected to control circuits 1352_1, charge pump 1350_2 is connected to control circuits 1352_2 . . . and charge pump 1350_n is connected to control circuits 1352_n. Each charge pump 1350_1 to 1350_n may be configured similarly to charge pump 117 of FIG. 9, with a control signal or signals controlling switching of one or more switching stages. Each control signal is sent to a respective control circuit. Each control circuits 1352_1 to 1352_n may be configured similarly to control circuits 904, with a pulse counter and register to perform characterization of respective charge pumps 1350_1 to 1350_n. Control circuits 1352_1 to 1352_n may be considered an example of means for counting, for each charge pump of a plurality of charge pumps, a number of pulses from regulation circuits to switches within a predetermined time period while the charge pump outputs a predetermined current to measure charge pump strength of the plurality of charge pumps and storing the number of pulses

FIG. 13B illustrates a second embodiment that includes a plurality of pumps (n charge pumps), 1350_1, 1350_2 . . . 1350_n, which may be formed on the same die. All charge pumps are connected to common control circuits 1352. For example, charge pump 1350_1 is connected to control circuits 1352_1, charge pump 1350_2 is connected to control circuits 1352_2 . . . and charge pump 1350_n is connected to control circuits 1352_n. Each charge pump 1350_1 to 1350_n may be configured similarly to charge pump 117 of FIG. 9, with a control signal or signals controlling switching of one or more switching stages. Each control signal is sent to control circuit 1352, which may be configured similarly to control circuits 904 as shown in FIG. 12, with a pulse counter and register configured to count pulses from multiple charge pumps and store the resulting counts. Control circuit 1352 may be considered an example of means for counting, for each charge pump of a plurality of charge pumps, a number of pulses from the regulation circuits to the switches within a predetermined time period while the charge pump outputs a predetermined current to measure charge pump strength of the plurality of charge pumps and storing the number of pulses

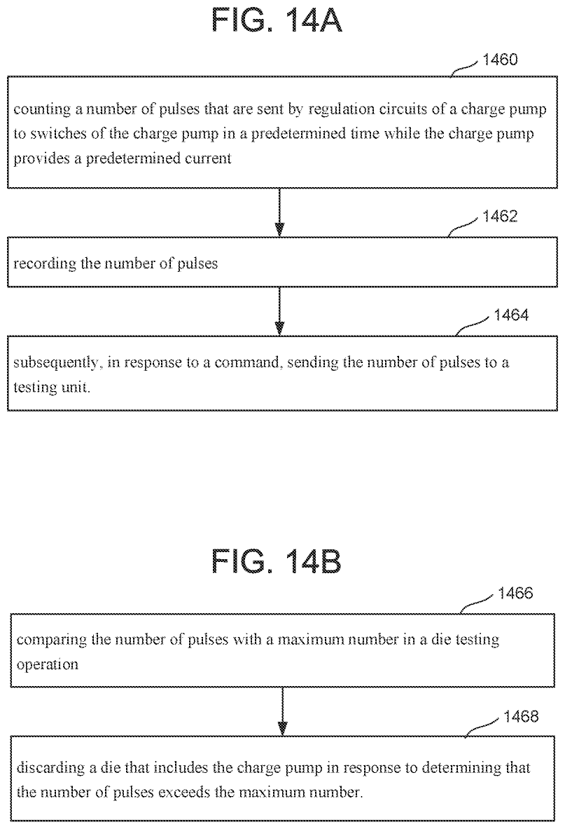

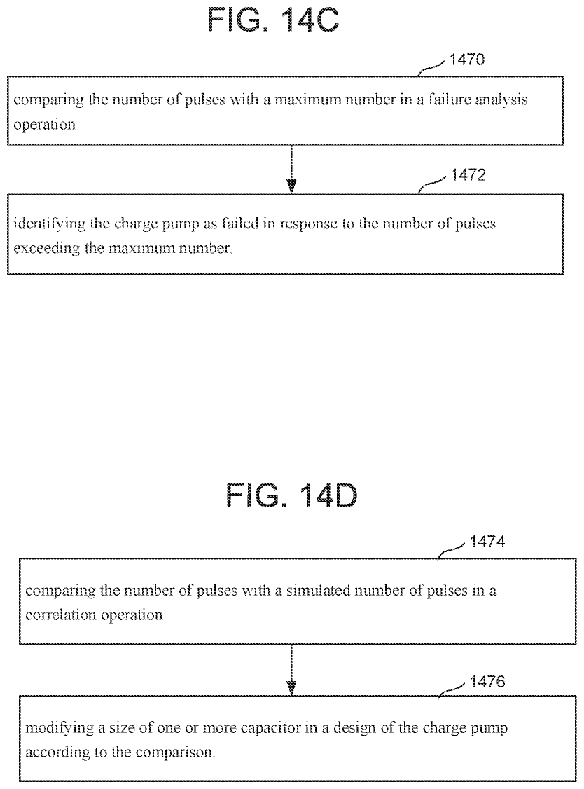

FIG. 14 shows an example of a method that implements aspects of the present technology. The method includes counting a number of pulses that are sent by regulation circuits of a charge pump (e.g., regulation circuits 616) to switches of the charge pump in a predetermined time while the charge pump provides a predetermined current 1460 (e.g., with a calibrated current source connected), recording the number of pulses 1462 and subsequently, in response to a command, sending the number of pulses to a testing unit 1464 (e.g., through a host interface).

Counts of the numbers of pulses obtained according to the method of FIG. 14A may be used in various ways. Some examples are provided in the optional, additional steps illustrated in FIGS. 14B-14D.

FIG. 14B shows an example of a method that includes comparing the number of pulses (e.g., from step 1464) with a maximum number in a die testing operation 1466 and discarding a die that includes the charge pump in response to determining that the number of pulses exceeds the maximum number 1468. For example, a die that includes one or more charge pumps that require an excessive number of switching operations (switching frequency above a maximum) to maintain a given output voltage and current may be considered defective and may be discarded.

FIG. 14C shows an example of a method that includes comparing the number of pulses (e.g., from step 1464) with a maximum number in a failure analysis operation 1470 (e.g., where a product has failed and been returned by a customer) and identifying the charge pump as failed in response to the number of pulses exceeding the maximum number 1472.

FIG. 14D shows an example of a method that includes comparing the number of pulses with a simulated number of pulses in a correlation operation 1474 and modifying a size of one or more capacitor in a design of the charge pump according to the comparison 1476. For example, when the number of pulses is less than indicated by simulation (e.g., as illustrated in FIG. 11) this indicates that a charge pump is stronger than needed and capacitor size may be reduced thereby saving space.

An example of an apparatus includes one or more control circuits configured to connect to a plurality of nonvolatile memory cells. The one or more control circuits are configured to count a number of pulses sent to switches of a charge pump, record the count of the number of pulses sent to the switches and send the count of the number of pulses in response to a request for the count of the number of pulses.

The one or more control circuits may be configured to count the pulses for a predetermined period of time while the charge pump provides a constant current. The one or more control circuits may include a pulse counter connected to an output of regulation circuits of the charge pump to count the number of pulses generated by the regulation circuits, a register to store the number and communication circuits to receive a command and send the number. The regulation circuits may include a comparator, the comparator having a first input connected to an output terminal of the charge pump through a voltage divider and a second input connected to a reference voltage, the comparator configured to provide a comparator output signal indicating when an output voltage at the output terminal of the charge pump is below a predetermined voltage. The regulation circuits may include a switch having the comparator output signal as a first switch input and a clock signal as a second switch input, the switch configured to provide pulses of the clock signal as a switch output only when the comparator output signal indicates that the output voltage at the output terminal of the charge pump is below the predetermined voltage. The output of the switch may be provided as the output of regulation circuits of the charge pump that is provided to the switches of the charge pump. The one or more control circuits may include a counter that is configured to count the number of pulses over a predetermined time. The one or more control circuits may include a register that is configured to store the number of pulses. The number of pulses stored in the register may be readable in response to a command directed to the register. The one or more control circuits may be located on a memory die that includes the plurality of nonvolatile memory cells, the memory die may include a plurality of additional charge pumps and the one or more control circuits may be configured to count additional numbers of pulses provided to switches of the additional charge pumps and record the additional numbers as indicators of output currents of the additional charge pumps. The one or more control circuits may be located on a control die that is separate from a memory die that includes the plurality of nonvolatile memory cells, the control die may include a plurality of additional charge pumps and the one or more control circuits may be configured to count additional numbers of pulses provided to switches of the additional charge pumps and record the additional numbers as indicators of output currents of the additional charge pumps.

An example of a method includes counting a number of pulses that are sent by regulation circuits of a charge pump to switches of the charge pump in a predetermined time while the charge pump provides a predetermined current; recording the number of pulses; and subsequently, in response to a command, sending the number of pulses to a testing unit.

The method may further include comparing the number of pulses with a maximum number in a die testing operation; and discarding a die that includes the charge pump in response to determining that the number of pulses exceeds the maximum number. The method may include comparing the number of pulses with a maximum number in a failure analysis operation; and identifying the charge pump as failed in response to the number of pulses exceeding the maximum number. The method may include comparing the number of pulses with a simulated number of pulses in a correlation operation; and modifying a size of one or more capacitor in a design of the charge pump according to a result of the comparing. The method may include counting one or more additional numbers of pulses that are sent by the regulation circuits in the predetermined time while the charge pump provides one or more additional predetermined current. The method may further include connecting the testing unit to a memory system that includes the charge pump through a host interface; subsequently, initiating counting and recording of pulses by control circuits of the memory system while the charge pump has an output connected to a constant current source; and sending the number of pulses to the testing unit through the host interface.

An example of a memory system includes a plurality of nonvolatile memory cells; a plurality of charge pumps connected to provide a plurality of voltages for accessing the plurality of nonvolatile memory cells, each charge pump having a plurality of capacitors and switches controlled by regulation circuits; and means for counting, for each charge pump of the plurality of charge pumps, a number of pulses from the regulation circuits to the switches within a predetermined time period while the charge pump outputs a predetermined current to measure charge pump strength of the plurality of charge pumps and storing the number of pulses.

In some examples, the plurality of nonvolatile memory cells are located on a memory die; the plurality of charge pumps are located on the memory die; the means for counting is located on the memory die; and the memory die is connected to a testing unit through a host interface of a memory controller connected to the memory die to enable reading of the number of pulses that is stored for each charge pump. In some examples, the plurality of nonvolatile memory cells are located on a memory die; the plurality of charge pumps are located on a control die that is connected to the memory die in an integrated memory assembly; the means for counting is located on the control die in the integrated memory assembly; and the integrated memory assembly is connected to a testing unit through a host interface of a memory controller connected to the integrated memory assembly to enable reading of the number of pulses that is stored for each charge pump.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus, comprising:
one or more control circuits configured to connect to a plurality of nonvolatile memory cells, the one or more control circuits are configured to:
count a number of pulses sent to switches of a charge pump, record the count of the number of pulses sent to the switches and send the count of the number of pulses in response to a request for the count of the number of pulses.

2. The apparatus of claim 1, wherein the one or more control circuits are configured to count the pulses for a predetermined period of time while the charge pump provides a constant current.

3. The apparatus of claim 1, wherein the one or more control circuits include a pulse counter connected to an output of regulation circuits of the charge pump to count the number of pulses generated by the regulation circuits, a register to store the number and communication circuits to receive a command and send the number.

4. The apparatus of claim 3, wherein the regulation circuits include a comparator, the comparator having a first input connected to an output terminal of the charge pump through a voltage divider and a second input connected to a reference voltage, the comparator configured to provide a comparator output signal indicating when an output voltage at the output terminal of the charge pump is below a predetermined voltage.

5. The apparatus of claim 4, wherein the regulation circuits include a switch having the comparator output signal as a first switch input and a clock signal as a second switch input, the switch configured to provide pulses of the clock signal as a switch output only when the comparator output signal indicates that the output voltage at the output terminal of the charge pump is below the predetermined voltage.

6. The apparatus of claim 5, wherein the output of the switch is provided as the output of regulation circuits of the charge pump that is provided to the switches of the charge pump.

7. The apparatus of claim 1, wherein the one or more control circuits include a counter that is configured to count the number of pulses over a predetermined time.

8. The apparatus of claim 7, wherein the one or more control circuits include a register that is configured to store the number of pulses.

9. The apparatus of claim 5, wherein the number of pulses stored in the register is readable in response to a command directed to the register.

10. The apparatus of claim 1, wherein the one or more control circuits are located on a memory die that includes the plurality of nonvolatile memory cells, the memory die includes a plurality of additional charge pumps and the one or more control circuits are configured to count additional numbers of pulses provided to switches of the additional charge pumps and record the additional numbers as indicators of output currents of the additional charge pumps.

11. The apparatus of claim 1, wherein the one or more control circuits are located on a control die that is separate from a memory die that includes the plurality of nonvolatile memory cells, the control die includes a plurality of additional charge pumps and the one or more control circuits are configured to count additional numbers of pulses provided to switches of the additional charge pumps and record the additional numbers as indicators of output currents of the additional charge pumps.

12. A method comprising:
counting a number of pulses that are sent by regulation circuits of a charge pump to switches of the charge pump in a predetermined time while the charge pump provides a predetermined current;
recording the number of pulses; and
subsequently, in response to a command, sending the number of pulses to a testing unit.

13. The method of claim 12, further comprising:
comparing the number of pulses with a maximum number in a die testing operation; and
discarding a die that includes the charge pump in response to determining that the number of pulses exceeds the maximum number.

14. The method of claim 12, further comprising:
comparing the number of pulses with a maximum number in a failure analysis operation; and
identifying the charge pump as failed in response to the number of pulses exceeding the maximum number.

15. The method of claim 12, further comprising:
comparing the number of pulses with a simulated number of pulses in a correlation operation; and
modifying a size of one or more capacitor in a design of the charge pump according to a result of the comparing.

16. The method of claim 12, further comprising counting one or more additional numbers of pulses that are sent by the regulation circuits in the predetermined time while the charge pump provides one or more additional predetermined current.

17. The method of claim 12, further comprising:
connecting the testing unit to a memory system that includes the charge pump through a host interface;
subsequently, initiating counting and recording of pulses by control circuits of the memory system while the charge pump has an output connected to a constant current source; and
sending the number of pulses to the testing unit through the host interface.

18. A memory system comprising:
a plurality of nonvolatile memory cells;
a plurality of charge pumps connected to provide a plurality of voltages for accessing the plurality of nonvolatile memory cells, each charge pump having a plurality of capacitors and switches controlled by regulation circuits; and
means for counting, for each charge pump of the plurality of charge pumps, a number of pulses from the regulation circuits to the switches within a predetermined time period while the charge pump outputs a predetermined current to measure charge pump strength of the plurality of charge pumps and storing the number of pulses.

19. The memory system of claim 18, wherein:
the plurality of nonvolatile memory cells are located on a memory die;
the plurality of charge pumps are located on the memory die;
the means for counting is located on the memory die; and
the memory die is connected to a testing unit through a host interface of a memory controller connected to the memory die to enable reading of the number of pulses that is stored for each charge pump.

20. The memory system of claim 18, wherein:
the plurality of nonvolatile memory cells are located on a memory die;
the plurality of charge pumps are located on a control die that is connected to the memory die in an integrated memory assembly;
the means for counting is located on the control die in the integrated memory assembly; and
the integrated memory assembly is connected to a testing unit through a host interface of a memory controller connected to the integrated memory assembly to enable reading of the number of pulses that is stored for each charge pump.
